(19) United States
(12) Patent Application Publication
(10) Pub. No.: US 2016/0315029 A1
(43) Pub. Date: Oct. 27, 2016

(54) SEMICONDUCTOR PACKAGE AND THREE-DIMENSIONAL SEMICONDUCTOR PACKAGE INCLUDING THE SAME

(71) Applicants: Dong-Han LEE, Seongnam-si (KR); Je-Gil MOON, Seoul (KR); Wook KIM, Yongin-si (KR); Min-Seon AHN, Hwaseong-si (KR); Yun-Hyeok IM, Hwaseong-si (KR); Kee-Moon CHUN, Seongnam-si (KR); Jae-Soo CHAUNG, Suwon-si (KR); Bum-Keun CHOI, Hwaseong-si (KR); Jung-Su HA, Osan-si (KR)

(72) Inventors: Dong-Han LEE, Seongnam-si (KR); Je-Gil MOON, Seoul (KR); Wook KIM, Yongin-si (KR); Min-Seon AHN, Hwaseong-si (KR); Yun-Hyeok IM, Hwaseong-si (KR); Kee-Moon CHUN, Seongnam-si (KR); Jae-Soo CHAUNG, Suwon-si (KR); Bum-Keun CHOI, Hwaseong-si (KR); Jung-Su HA, Osan-si (KR)

(21) Appl. No.: 15/019,013

(22) Filed: Feb. 9, 2016

(30) Foreign Application Priority Data
Apr. 23, 2015 (KR) 10-2015-0057271

(51) Int. Cl. H01L 23/367; H01L 25/065; H01L 23/48; H01L 23/00

(52) U.S. Cl. CPC H01L 23/3675; H01L 24/14; H01L 25/0657; H01L 23/481; H01L 2924/1432; H01L 2225/06541; H01L 2225/06589; H01L 2225/06513

(57) ABSTRACT

There is provided a semiconductor package including: a semiconductor chip; and an extension die provided on the semiconductor chip, wherein the semiconductor chip includes a heating point configured to generate a temperature greater than or equal to a pre-determined reference temperature in the semiconductor chip, the heating point provided in a center region of the extension die

### CROSS-REFERENCE TO RELATED APPLICATION

This U.S. Non-provisional application claims priority from Korean Patent Application No. 10-2015-0057271, filed on Apr. 23, 2015, in the Korean Intellectual Property Office (KIPO), the disclosure of which is incorporated herein by reference in its entirety.

### BACKGROUND

1. Technical Field

Apparatuses consistent with exemplary embodiments relate to a semiconductor device, and more particularly to a semiconductor package and a three-dimensional semiconductor package including the same.

2. Discussion of the Related Art

Recently, performance capacity of semiconductor device has increased according to development of various functions included in an electronic device. The performance capacity increase of the semiconductor device may cause heating problem of the semiconductor device. Various researches have been proceeded to solve the heating problem of the semiconductor device.

### SUMMARY

At least one exemplary embodiment of the inventive concept provides a semiconductor package enhancing performance by disposing heating point of semiconductor chip in center region corresponding to center of extension die.

At least one exemplary embodiment of the inventive concept provides a three-dimensional semiconductor package enhancing performance by disposing heating point of semiconductor chip in center region corresponding to center of extension die.

According to an aspect of an exemplary embodiment, there is provided a semiconductor package including a semiconductor chip and an extension die. The extension die is combined to the semiconductor chip. A heating point corresponding to a point generating heat greater than or equal to a pre-determined reference temperature in the semiconductor chip is disposed in a center region corresponding to center of the extension die.

In an exemplary embodiment, a size of the extension die may be larger than a size of the semiconductor chip.

In an exemplary embodiment, the extension die may include an extension layer and a side layer. The extension layer may be combined to a first surface of the semiconductor chip. The side layer may be disposed on the extension layer and may be combined to a side of the semiconductor chip.

In an exemplary embodiment, a height of the side layer may be the same as a height of the semiconductor chip.

In an exemplary embodiment, the extension die may further include side bumps disposed on the side layer.

In an exemplary embodiment, sizes of the side bumps may be the same as sizes of bumps combined to a second surface of the semiconductor chip.

In an exemplary embodiment, the semiconductor package may transfer signals through a signal line connected between the semiconductor chip and the side bumps.

In an exemplary embodiment, the semiconductor package may transfer a supply voltage through a power line connected between the semiconductor chip and the side bumps.

In an exemplary embodiment, the extension die may further include an additional side layer disposed on the side layer.

In an exemplary embodiment, a height of the additional side layer may be the same as a height of bumps combined to a second surface of the semiconductor chip.

In an exemplary embodiment, the heating point may be pre-determined in a test procedure of the semiconductor chip.

In an exemplary embodiment, the heating point may be a point, which has a temperature equal to or larger than the pre-determined temperature, on the semiconductor chip.

In an exemplary embodiment, if the semiconductor chip has a plurality of the heating points, the highest temperature heating point corresponding to the highest temperature among the plurality of the heating points may be disposed in the center region of the extension die.

In an exemplary embodiment, if the semiconductor chip includes a plurality of the heating points, the semiconductor package may include a plurality of the extension dies.

In an exemplary embodiment, each of the plurality of the heating points may be disposed in a center region of each of the plurality of the extension dies corresponding to the plurality of the heating points.

In an exemplary embodiment, if temperature of a certain point in the semiconductor chip is equal to or larger than the reference temperature during a pre-determined period, the certain point may correspond to the heating point.

In an exemplary embodiment, the heating point may be determined according to operation time of component included in the semiconductor chip.

In an exemplary embodiment, the heating point may be a point corresponding to a central processing unit (CPU) included in the semiconductor chip.

In an exemplary embodiment, the heating point may be a point corresponding to a graphic processing unit (GPU) included in the semiconductor chip.

According to an aspect of another exemplary embodiment, there is provided a three-dimensional semiconductor package including a plurality of semiconductor packages, and through silicon vias. Each of the plurality of the semiconductor packages includes a semiconductor chip, and an extension die. The through silicon vias connects the plurality of the semiconductor packages. The extension die is combined to the semiconductor chip. A heating point corresponding to a point generating heat equal to or larger than a pre-determined reference temperature in the semiconductor chip may be disposed in a center region corresponding to the center of the extension die.

In an exemplary embodiment, the extension die may include an extension layer, a side layer, and side bumps. The extension layer may be combined to a first surface of the semiconductor chip. The side layer may be disposed on the extension layer and may be combined to a side of the semiconductor chip. The side bumps may be disposed on the side layer.

In an exemplary embodiment, the extension die may include an extension layer, a side payer, and an additional side layer. The extension layer may be combined to a first surface of the semiconductor chip. The side layer may be disposed on the extension layer and may be combined to a side of the semiconductor chip. The additional side layer may be disposed on the side layer.

In an exemplary embodiment, a height of the additional side layer may be the same as a height of bumps combined to a second surface of the semiconductor chip.

According to an aspect of another example embodiment, there is provided a three-dimensional semiconductor package including a plurality of semiconductor packages and an interposer. Each of the semiconductor packages includes a semiconductor chip and an extension die. The interposer connects the plurality of the semiconductor packages. The extension die is combined to the semiconductor chip. A heating point corresponding to a point generating heat equal to or larger than a pre-determined reference temperature in the semiconductor chip is disposed in a center region corresponding to the center of the extension die.

In an exemplary embodiment, the heating point may be pre-determined in a test procedure of the semiconductor chip. If temperature of a certain point in the semiconductor chip is equal to or larger than the reference temperature during a pre-determined period, the certain point may correspond to the heating point.

According to an aspect of another example embodiment, there is provided a semiconductor package including: a semiconductor chip; and an extension die provided on the semiconductor chip, wherein the semiconductor chip includes a heating point configured to generate a temperature greater than or equal to a pre-determined reference temperature in the semiconductor chip, the heating point provided in a center region of the extension die.

A size of the extension die may be larger than a size of the semiconductor chip.

The extension die may include: an extension layer attached to a first surface of the semiconductor chip; and a side layer which is provided on the extension layer and which is attached to a side of the semiconductor chip.

A height of the side layer may be equal to a height of the semiconductor chip.

The extension die may further include side bumps provided on the side layer.

Sizes of the side bumps may be equal to sizes of bumps attached to a second surface of the semiconductor chip.

The semiconductor package may be configured to transfer signals through a signal line connected between the semiconductor chip and the side bumps.

The semiconductor package may be configured to transfer a supply voltage through a power line connected between the semiconductor chip and the side bumps.

The extension die may further include an additional side layer provided on the side layer.

A height of the additional side layer may be equal to a height of the bumps attached to a second surface of the semiconductor chip.

The heating point may be pre-determined in a test procedure of the semiconductor chip.

The heating point may correspond to a point having a temperature greater than or equal to the pre-determined temperature, on the semiconductor chip.

In response to the semiconductor chip including a plurality of the heating points, a maximum temperature heating point corresponding to a heating point having the highest temperature among the plurality of the heating points may be provided in the center region of the extension die.

In response to the semiconductor chip including a plurality of the heating points, the semiconductor package may include a plurality of the extension dies.

Each of the plurality of the heating points may be disposed in a center region of each of the plurality of the extension dies corresponding to the plurality of the heating points.

In response to a temperature of a certain point in the semiconductor chip being greater than or equal to the reference temperature during a pre-determined period, the certain point may correspond to the heating point.

The heating point may be determined according to an operation time of a component included in the semiconductor chip.

The heating point may correspond to a location of a central processing unit (CPU) included in the semiconductor chip.

The heating point may correspond to a location of a graphic processing unit (GPU) included in the semiconductor chip.

According to an aspect of another example embodiment, there is provided a three-dimensional semiconductor package including: a plurality of semiconductor packages; and a via connecting the plurality of the semiconductor packages, wherein each of the plurality of the semiconductor packages includes: a semiconductor chip; and an extension die provided on the semiconductor chip, wherein the semiconductor chip includes a heating point configured to generate a temperature greater than or equal to a pre-determined reference temperature in the semiconductor chip, the heating point is provided in a center region of the extension die.

The via may include through silicon vias.

The extension die may include: an extension layer attached to a first surface of the semiconductor chip; a side layer which is provided on the extension layer and which is attached to a side of the semiconductor chip; and side bumps disposed on the side layer.

The extension die may include: an extension layer attached to a first surface of the semiconductor chip; a side layer which is provided on the extension layer and which is attached to a side of the semiconductor chip; and an additional side layer provided on the side layer.

A height of the additional side layer may be equal to a height of bumps attached to a second surface opposite to the first surface of the semiconductor chip.

According to an aspect of another example embodiment, there is provided a three-dimensional semiconductor package including: a plurality of semiconductor packages; and an interposer provided between the plurality of the semiconductor packages, wherein each of the plurality of the semiconductor packages includes: a semiconductor chip; and an extension die provided on the semiconductor chip, wherein the semiconductor chip includes a heating point configured to generate a temperature greater than or equal to a pre-determined reference temperature in the semiconductor chip, the heating point is provided in a center region of the extension die.

The heating point may be pre-determined in a test procedure of the semiconductor chip, wherein in response to a temperature of a point in the semiconductor chip being greater than or equal to the reference temperature during a pre-determined period, the point corresponds to the heating point.

According to an aspect of another example embodiment, there is provided a semiconductor package including: a semiconductor chip including a heating point configured to generate a temperature greater than or equal to a pre-determined reference temperature in the semiconductor chip; and an extension die attached to the semiconductor chip and configured to diffuse heat from the heating point of the semiconductor chip, wherein the extension die is attached to the semiconductor chip such that the heating point of the semiconductor chip is disposed in a center region of the extension die.

The heating point may correspond to a location of a component provided on the semiconductor chip.

The component may include at least one of a central processing unit (CPU) and a graphic processing unit (GPU).

As described above, a semiconductor package according to exemplary embodiments may enhance heat transfer performance by disposing heating point of semiconductor chip in center region corresponding to the center of extension die.

### BRIEF DESCRIPTION OF THE DRAWINGS

The above and/or other aspects of the disclosure will be more clearly understood from the following detailed description taken in conjunction with the accompanying drawings of which:

FIG. 1 is a diagram illustrating a semiconductor package according to an exemplary embodiments.

FIGS. 2A, 2B, and 2C are diagrams explaining limit temperature arrival time according to location of the heating point of the semiconductor chip.

FIG. 3 is a cross-sectional diagram illustrating an exemplary embodiment of vertical structure generated by cutting the semiconductor package of FIG. 1 along X line.

FIG. 4 is a diagram explaining height of the extension layer and the semiconductor chip of the semiconductor package of FIG. 3.

FIG. 5 is a diagram illustrating a semiconductor package according to an exemplary embodiment.

FIG. 6 is a diagram explaining size of the side bump and the bump included in the semiconductor package of FIG. 5.

FIG. 7 is a diagram illustrating an exemplary embodiment connecting the side bumps included in the semiconductor packages of FIG. 5 through the signal line.

FIG. 8 is a diagram illustrating an exemplary embodiment connecting the side bumps included in the semiconductor packages of FIG. 5 through the signal line and the power line.

FIG. 9 is a diagram illustrating a semiconductor package according to an exemplary embodiment.

FIG. 10 is a diagram explaining height of the additional side layer and the bump included in the semiconductor package of FIG. 9.

FIGS. 11 and 12 are diagrams explaining semiconductor package according to an exemplary embodiment.

FIGS. 13 and 14 are diagrams explaining semiconductor package according to another exemplary embodiment.

FIG. 15 is a diagram explaining an exemplary embodiment of method to determine the heating point included in the semiconductor chip.

FIGS. 16 and 17 are diagrams explaining another exemplary embodiment of method to determine the heating point included in the semiconductor chip.

FIG. 18 is a diagram illustrating a three-dimensional semiconductor package according to exemplary embodiments.

FIG. 19 is a diagram illustrating the first semiconductor package included in the three-dimensional semiconductor package of FIG. 18.

FIG. 20 is a diagram illustrating the second semiconductor package included in the three-dimensional semiconductor package of FIG. 18.

FIG. 21 is a diagram illustrating a three-dimensional semiconductor package according to exemplary embodiments.

FIG. 22 is a diagram illustrating the third semiconductor package included in the three-dimensional semiconductor package of FIG. 21.

FIG. 23 is a diagram illustrating the fourth semiconductor package included in the three-dimensional semiconductor package of FIG. 21.

FIG. 24 is a block diagram illustrating an exemplary embodiment of a mobile system applying the semiconductor package according to exemplary embodiments.

FIG. 25 is a block diagram illustrating an exemplary embodiment of a computing system applying the semiconductor package according to exemplary embodiments.

### DETAILED DESCRIPTION

Various exemplary embodiments will be described more fully hereinafter with reference to the accompanying drawings, in which some exemplary embodiments are shown. The present inventive concept may, however, be embodied in many different forms and should not be construed as limited to the exemplary embodiments set forth herein. Rather, these exemplary embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

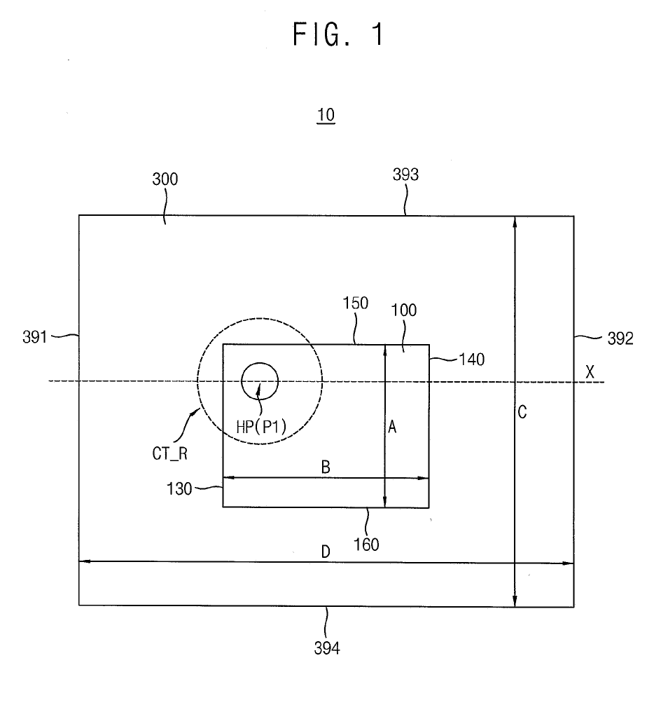

FIG. 1 is a diagram illustrating a semiconductor package 10 according to an exemplary embodiment.

Referring to FIG. 1, a semiconductor package 10 includes a semiconductor chip 100 and an extension die 300. The semiconductor chip 100 may include the heating point HP corresponding to a point generating heat greater than or equal to a pre-determined reference temperature R_T. The heating point HP may be determined in a test procedure of the semiconductor chip 100. The test procedure is executed prior to packaging process combining the semiconductor chip 100 and the extension die 300.

The extension die 300 is combined to the semiconductor chip 100. The extension die 300 may include a material having high thermal conductivity. For example, the extension die 300 may be made with copper Cu and silicon Si. When the extension die 300 is made with the material having high thermal conductivity, the extension die 300 may diffuse heat transferred from the heating point HP of the semiconductor chip 100. The extension die 300 may surround sides of the semiconductor chip 100. For example, the sides of the semiconductor chip 100 may include a first side 130, a second side 140, a third side 150, and a fourth side 160. For an exemplary embodiment, the extension die 300 may surround the first side 130, the second side 140, the third side 150, and the fourth side 160 of the semiconductor chip 100. For another exemplary embodiment, the extension die 300 may surround the first side 130 and the third side 150 of the semiconductor chip 100.

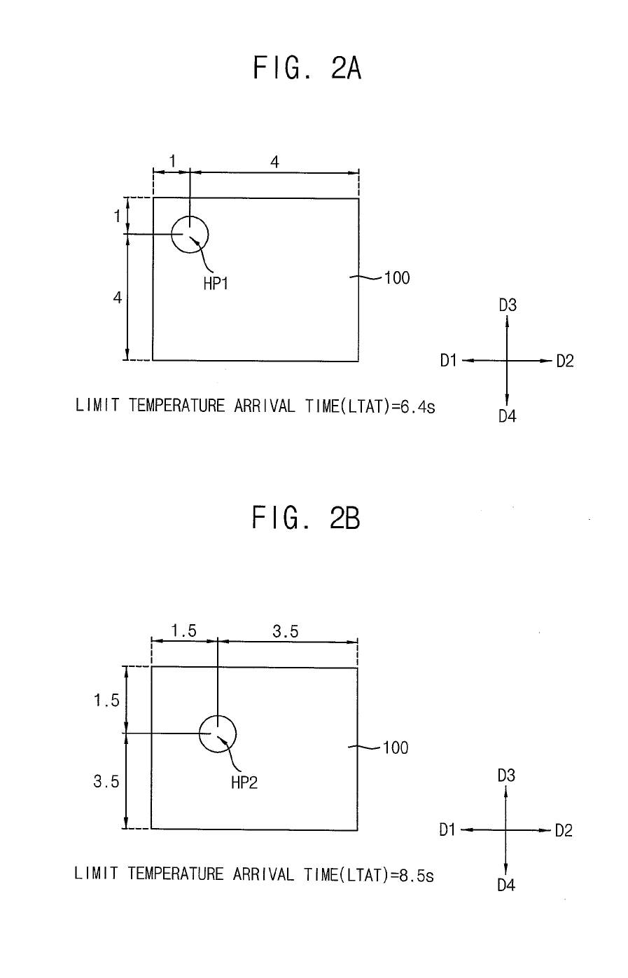

The heating point HP corresponding to a point generating heat greater than or equal to a pre-determined reference temperature R_T in the semiconductor chip 100 is disposed in a center region CT_R corresponding to the center of the extension die 300. For example, the pre-determined reference temperature R_T may be 120 Celsius degree (° C.). In the test procedure of the semiconductor chip 100 which is executed prior to the packaging procedure combining the semiconductor chip 100 and the extension die 300, temperature of the first point P1 included in the semiconductor chip 100 may be greater than or equal to 120° C. If temperature of the first point P1 included the semiconductor chip 100 is greater than or equal to 120° C., the first point P1 may be the heating point HP. If the first point P1 is the heating point HP, the first point P1 may be disposed in the center region CT_R corresponding to the center of the extension die 300. If the heating point HP is disposed in the center region CT_R corresponding to the center of the extension die 300, heat transferred from the heating point HP may be diffused rapidly through the extension die 300. If the heating point HP is not disposed in the center region CT_R corresponding to the center of the extension die 300, heat transferred from the heating point HP may be diffused slowly through the extension die 300. This case will be described with the references to FIGS. 2A, 2B, and 2C.

In an exemplary embodiment, a size of the extension die 300 may be larger than a size of the semiconductor chip 100. For example, the sides of the semiconductor chip 100 may include the first side 130, the second side 140, the third side 150, and a fourth side 160. The length of the first side 130 and the second side 140 of the semiconductor chip 100 may be a first length A. The length of the third side 150 and the fourth side 160 of the semiconductor chip 100 may be a second length B. A side of the extension die 300 corresponding to the first side 130 of the semiconductor chip 100 may be a first extension side 391. A side of the extension die 300 corresponding to the second side 140 of the semiconductor chip 100 may be a second extension side 392. A side of the extension die 300 corresponding to the third side 150 of the semiconductor chip 100 may be a third extension side 393. A side of the extension die 300 corresponding to the fourth side 160 of the semiconductor chip 100 may be a fourth extension side 394.

Lengths of the first extension side 391 and the second extension side 392 of the extension die 300 may be a third length C, and length of the third extension side 393 and the fourth extension side 394 of the extension die 300 may be a fourth length D. The third length C may be larger than the first length A. The fourth length D may be larger than the second length B. In this case, the size of the extension die 300 may be larger than the size of the semiconductor chip 100. If the size of the extension die 300 is larger than the size of the semiconductor chip 100, heat transferred from the heating point HP may be diffused rapidly through the extension die 300. The semiconductor package 10 according to exemplary embodiments may enhance heat transfer performance by disposing the heating point HP of the semiconductor chip 100 in the center region CT_R corresponding to the center of the extension die 300.

FIGS. 2A, 2B, and 2C are diagrams explaining limit temperature arrival time (LTAT) according to a location of the heating point of the semiconductor chip 100.

Referring to FIGS. 2A, 2B, and 2C, the LTAT, which is time to reach a pre-determined limit temperature, may be changed according to the location of the heating point HP of the semiconductor chip 100. For example, the heating point HP of the semiconductor chip 100 may be a first heating point HP1 as shown in FIG. 2A. If the heating point HP of the semiconductor chip 100 is the first heating point HP1, a distance from the first heating point HP1 to the first side 130 of the semiconductor chip 100 along the first direction D1 may be 1, a distance from the first heating point HP1 to the second side 140 of the semiconductor chip 100 along the second direction D2 may be 4, a distance from the first heating point HP1 to the third side 150 of the semiconductor chip 100 along the third direction D3 may be 1, and a distance from the first heating point HP1 to the fourth side 160 of the semiconductor chip 100 along the fourth direction D4 may be 4. If heating point HP of the semiconductor chip 100 is the first heating point HP1, heat transferred from the first heating point HP1 may be diffused rapidly along the second direction D2 and the fourth direction D4. On the other hand, if heating point HP of the semiconductor chip 100 is the first heating point HP1, heat transferred from the first heating point HP1 may be diffused slowly along the first direction D1 and the third direction D3. In this case, the limit temperature arrival time LTAT of the heating point HP may be 6.4 seconds.

In another example, the heating point HP of the semiconductor chip 100 may be a second heating point HP2. If the heating point HP of the semiconductor chip 100 is the second heating point HP2, a distance from the second heating point HP2 to the first side 130 of the semiconductor chip 100 along the first direction D1 may be 1.5, a distance from the second heating point HP2 to the second side 140 of the semiconductor chip 100 along the second direction D2 may be 3.5, a distance from the second heating point HP2 to the third side 150 of the semiconductor chip 100 along the third direction D3 may be 1.5, and a distance from the second heating point HP2 to the fourth side 160 of the semiconductor chip 100 along the fourth direction D4 may be 3.5. If heating point HP of the semiconductor chip 100 is the second heating point HP2, heat transferred from the second heating point HP2 may be diffused rapidly along the second direction D2 and the fourth direction D4. On the other hand, if heating point HP of the semiconductor chip 100 is the second heating point HP2, heat transferred from the second heating point HP2 may be diffused slowly along the first direction D1 and the third direction D3. In this case, the limit temperature arrival time LTAT of the heating point HP may be 8.5 seconds. Diffusing speed of the heat, which is transferred from the second heating point HP2, along the first direction D1 and the third direction D3 in FIG. 2B may be faster than diffusing speed of the heat, which is transferred from the first heating point HP1, along the first direction D1 and the third direction D3 in FIG. 2A.

For example, the heating point HP of the semiconductor chip 100 may be a third heating point HP3. If the heating point HP of the semiconductor chip 100 is the third heating point HP3, a distance from the third heating point HP3 to the first side 130 of the semiconductor chip 100 along the first direction D1 may be 2.5, a distance from the third heating point HP3 to the second side 140 of the semiconductor chip 100 along the second direction D2 may be 2.5, a distance from the third heating point HP3 to the third side 150 of the semiconductor 100 along the third direction D3 may be 2.5, and a distance from the third heating point HP3 to the fourth side 160 of the semiconductor chip 100 along the fourth direction D4 may be 2.5. If heating point HP of the semiconductor chip 100 is the third heating point HP3, heat transferred from the third heating point HP3 may be diffused rapidly along the first direction D1, the second direction D2, the third direction D3, and the fourth direction D4. In this case, the LTAT of the heating point HP may be 11.5 seconds. Diffusing speed of the heat, which is transferred from the third heating point HP3, along the first direction D1 and the third direction D3 in FIG. 2C may be faster than diffusing speed of the heat, which is transferred from the second heating point HP2, along the first direction D1 and the third direction D3 in FIG. 2B.

Smaller distance between the heating point HP and center of the semiconductor chip 100 may cause faster diffusing speed of heat transferred from the heating point HP. If heat transferred from the heating point HP is diffused rapidly, the limit temperature arrival time LTAT may increase. However, the heating point HP may not be disposed in center of the semiconductor chip 100 in the chip design step. If the heating point HP is not disposed at the center of the semiconductor chip 100 during the chip design step, the heating point HP of the semiconductor chip 100 may be disposed in the center region CT_R of the extension die 300 by using the extension die 300. If the heating point HP of the semiconductor chip 100 is disposed in the center region CT_R of the extension die 300, heat transferred from the heating point HP may be diffused rapidly. The semiconductor package 10 according to exemplary embodiments may enhance heat transfer performance by disposing the heating point HP of the semiconductor chip 100 in the center region CT_R corresponding to the center of the extension die 300.

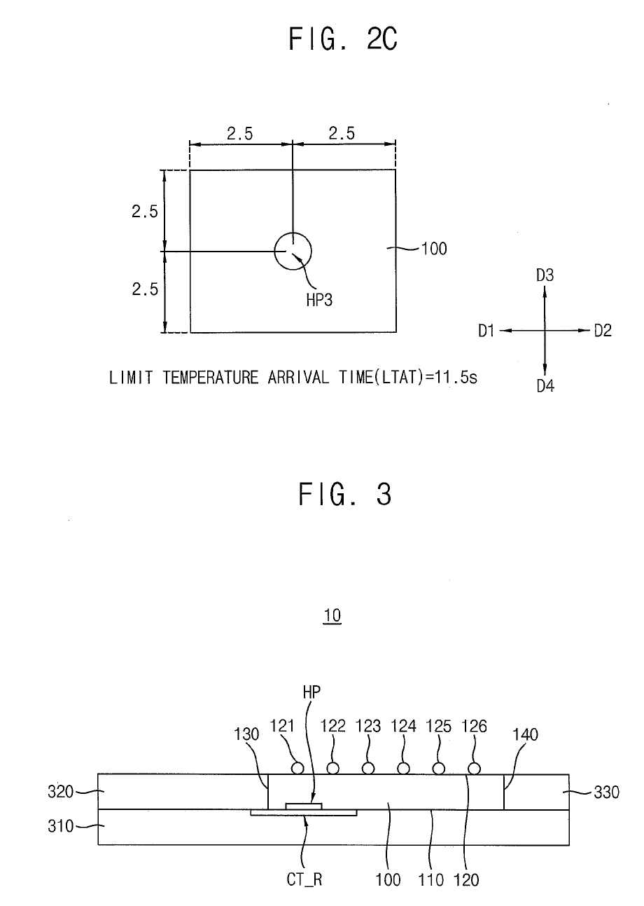

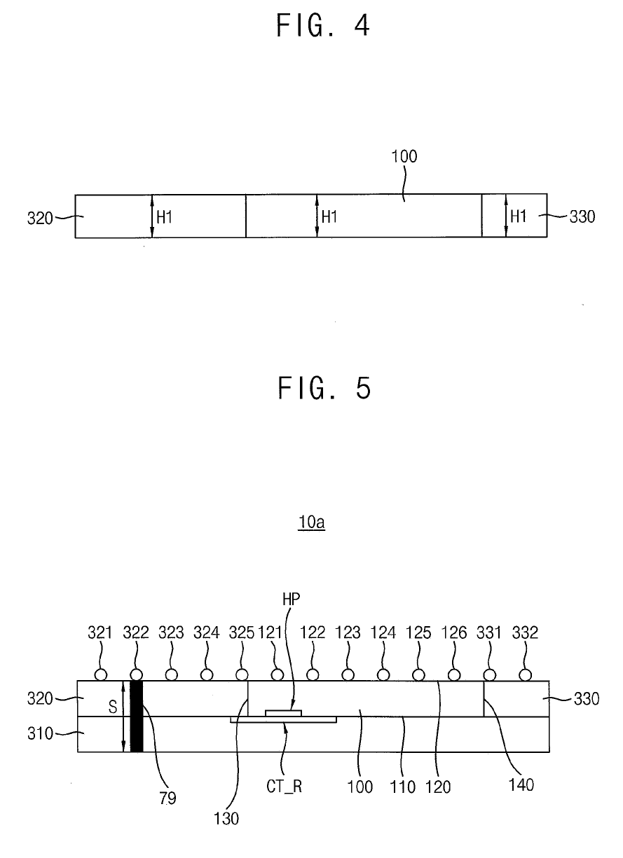

FIG. 3 is a cross-sectional diagram illustrating an exemplary embodiment of a vertical structure generated by cutting the semiconductor package of FIG. 1 along a line X in FIG. 1. FIG. 4 is a diagram explaining a height of an extension layer and the semiconductor chip of the semiconductor package of FIG. 3.

Referring to FIGS. 3 and 4, the semiconductor package 10 includes the semiconductor chip 100 and the extension die 300. The extension die 300 is combined to the semiconductor chip 100. The heating point HP corresponding to a point generating heat equal to or larger than the pre-determined reference temperature R_T in the semiconductor chip 100 is disposed in the center region CT_R corresponding to the center of the extension die 300. In an exemplary embodiment, the extension die 300 may include an extension layer 310 and a side layer 320 and 330. The extension layer 310 may be combined to a first surface 110 of the semiconductor chip 100. For example, the first surface 110 of the semiconductor chip 100 may be connected to the extension layer 310, and a second surface 120 of the semiconductor chip 100 may be connected to the bumps. The side layer 320 and 330 may be disposed on the extension layer 310 and may be combined to a side of the semiconductor chip 100.

For example, the side layer 320 and 330 may include a first side layer 320 and a second side layer 330. The first side layer 320 may be disposed on the extension layer 310 and may be combined to the first side 130 of the semiconductor chip 100. The second side layer 330 may be disposed on the extension layer 310 and may be combined to the second side 140 of the semiconductor chip 100. The extension layer 310 included in the extension die 300 may include a material having high thermal conductivity. For example, the extension layer 310 included in the extension die 300 may be made with copper Cu and silicon Si. When the extension layer 310 included in the extension die 300 is made with the material having high thermal conductivity, the extension layer 310 included in the extension die 300 may diffuse heat transferred from the heating point HP of the semiconductor chip 100 rapidly. Also, the first side layer 320 and the second side layer 330 included in the extension die 300 may be made with copper Cu and silicon Si. When the first side layer 320 and the second side layer 330 included in the extension die 300 is made with the material having high thermal conductivity, the extension layer 310 included in the extension die 300 may diffuse heat transferred from the heating point HP of the semiconductor chip 100 rapidly.

In an exemplary embodiment, the height of the side layer 320 and 330 may be the same as the height of the semiconductor chip 100. For example, the side layer 320 and 330 may include the first side layer 320 and the second side layer 330. The height of the semiconductor chip 100 may be a first height H1. If the height of the semiconductor chip 100 is equal to the first height H1, the height of the first side layer 320 may be the first height H1. Also, if the height of the semiconductor chip 100 is equal to the first height H1, the height of the second side layer 330 may be the first height H1. The semiconductor package 10 according to the exemplary embodiments may enhance heat transfer performance by disposing the heating point HP of the semiconductor chip 100 in the center region CT_R corresponding to the center of the extension die 300.

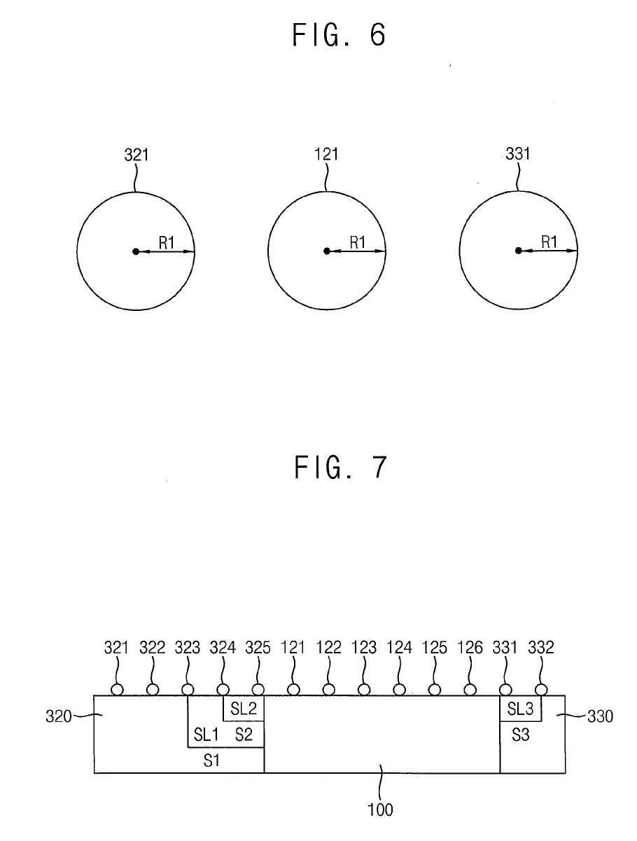

FIG. 5 is a diagram illustrating a semiconductor package 10a according to an exemplary embodiment. FIG. 6 is a diagram explaining sizes of side bumps 321 through 325, 331, and 332 and bumps 121 through 126 included in the semiconductor package 10 of FIG. 5.

Referring to FIGS. 5 and 6, the semiconductor package 10a includes the semiconductor chip 100 and the extension die 300. The extension die 300 is combined to the semiconductor chip 100. The heating point HP corresponding to a point generating heat greater than or equal to the pre-determined reference temperature R_T in the semiconductor chip 100 is disposed in the center region CT_R corresponding to the center of the extension die 300. The extension die 300 includes an extension layer 310 and a first side layer 320 and a second side layer 330. The extension layer 310 may be attached to the first surface 110 of the semiconductor chip 100. For example, a first surface 110 of the semiconductor chip 100 may be connected to the extension layer 310, and a second surface 120 of the semiconductor chip 100 may be connected to the bumps 121 through 126. The first side layer 320 and the second side layer 330 may be disposed on the extension layer 310 and may be combined to a respective side of the semiconductor chip 100. In an exemplary embodiment, the extension die 300 may further include the side bumps 321 through 325, 331, and 332 disposed on the first and the second side layers 320 and 330. The side bumps 321 through 325, 331, and 332 disposed on the first side layer 320 may be the first through fifth side bumps 321 through 325. Also, the side bumps disposed on the second side layer 330 may be the sixth and seventh side bumps 331 and 332 as shown in FIG. 5. Heat, which is transferred from the heating point HP included in the semiconductor chip 100, may be transferred through the first through fifth side bumps 321 through 325 and the sixth and seventh side bumps 331 and 332. In an exemplary embodiment, the extension die 300 included in the semiconductor package 10 may further include a through silicon via 79. For example, the second side bump 322, which is disposed on the first side layer 320 included in the extension die 300, may be connected to the through silicon via 79. If the second side bump 322 is connected to the through silicon via 79, the second side bump 322 may receive the signal S, which is transferred from lower side of the extension die 300, through the through silicon via 79. In the exemplary embodiment, the second side bump 322 may transfer the signal S to a circuit disposed on upper side of the extension die 300.

In an exemplary embodiment, sizes of the side bumps 321 through 325, 331, and 332 may be the same as sizes of the bumps 121 through 126 combined to the second surface 120 of the semiconductor chip 100. For example, the first through fifth side bumps 321 through 325 may be disposed on the first side layer 320. Sizes of the first through fifth side bumps 321 through 325 may be the same with one another. Also, the first through sixth bumps 121 through 126 may be disposed on the second surface 120 of the semiconductor chip 100. Sizes of the first through sixth bumps 121 through 126 may be the same with one another. Also, the sixth and seventh side bumps 331 and 332 may be disposed on the second side layer 330. Sizes of the sixth and seventh side bumps 331 and 332 may be the same with each other. For example, radius of the first bump 121 may be the first radius R1. If the radius of the first bump 121 is the first radius R1, radius of the first side bump 321 may be the first radius R1. Also, if the radius of the first bump 121 is the first radius R1, radius of the sixth side bump 331 may be the first radius R1.

The semiconductor package 10 according to the exemplary embodiments may enhance heat transfer performance by disposing the heating point HP of the semiconductor chip 100 in the center region CT_R corresponding to the center of the extension die 300.

FIG. 7 is a diagram illustrating an exemplary embodiment connecting the side bumps 321 through 325, 331, and 332 included in the semiconductor package 10a of FIG. 5 through signal lines SL1, SL2 and SL3.

Referring to FIGS. 5 and 7, the semiconductor package 10a includes the semiconductor chip 100 and the extension die 300. The extension die 300 is combined to the semiconductor chip 100. The heating point HP corresponding to a point generating heat greater than or equal to the pre-determined reference temperature R_T in the semiconductor chip 100 is disposed in the center region CT_R corresponding to the center of the extension die 300. The extension die 300 includes an extension layer 310 and a first side layer 320 and a second side layer 330. The extension layer 310 may be attached to the first surface 110 of the semiconductor chip 100. For example, the first surface 110 of the semiconductor chip 100 may be connected to the extension layer 310, and the second surface 120 of the semiconductor chip 100 may be connected to the bumps 121 through 126. The first and the second side layers 320 and 330 may be disposed on the extension layer 310 and may be combined to respective sides of the semiconductor chip 100. The extension die 300 may further include the side bumps 321 through 325, 331, and 332 disposed on the first and second side layers 320 and 330.

In an exemplary embodiment, the semiconductor package 10 may transfer signals through a signal line connected between the semiconductor chip 100 and the side bumps 321 through 325, 331, and 332. For example, a signal line connected between the semiconductor chip 100 and the third side bump 323 may be the first signal line SL1. If the signal line, which is connected between the semiconductor chip 100 and the third side bump 323 disposed on the first side layer 320, is the first signal line SL1, the first signal S1 may be transferred to the semiconductor chip 100 through the first signal line SL1. Furthermore, a signal line, which is connected between the semiconductor chip 100 and the fourth side bump 324 disposed on the first side layer 320, may be the second signal line SL2. If the signal line, which is connected between the semiconductor chip 100 and the fourth side bump 324, is the second signal line SL2, the second signal S2 may be transferred to the semiconductor chip 100 through the second signal line SL2. In the same way, a signal line, which is connected between the semiconductor chip 100 and the seventh side bump 332 disposed on the second side layer 330, may be the third signal line SL3. If the signal line, which is connected between the semiconductor chip 100 and the seventh side bump 332, is the third signal line SL3, the third signal S3 may be transferred to the semiconductor chip 100 through the third signal line SL3.

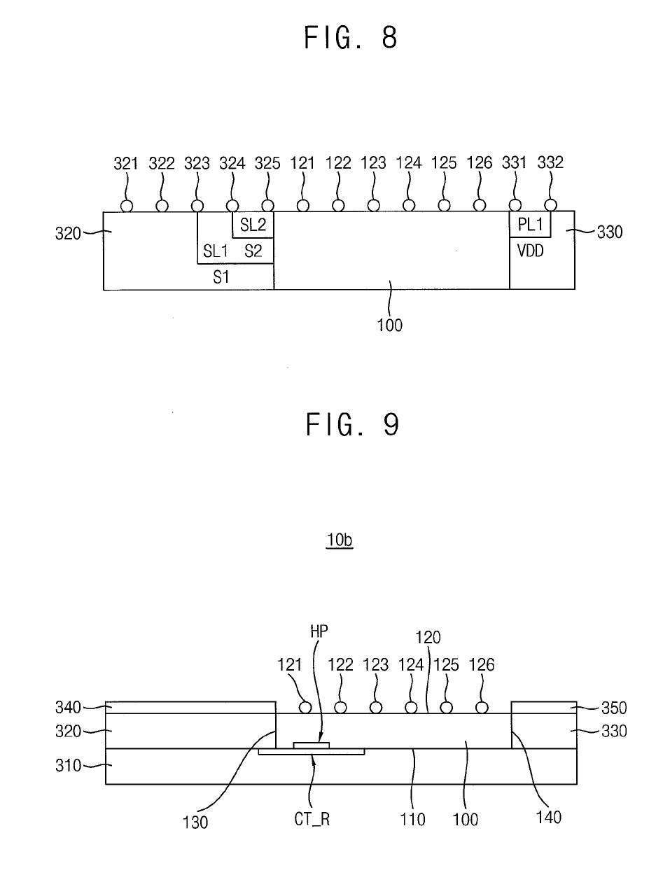

FIG. 8 is a diagram illustrating an exemplary embodiment connecting the side bumps 321 through 325, 331, and 332 included in the semiconductor package 10a of FIG. 5 through the signal lines SL1 and SL2 and a power line PL1.

Referring to FIG. 8, the semiconductor package 10 may transfer a supply voltage VDD through a power line PL1 connected between the semiconductor chip 100 and the side bumps 321 through 325, 331, and 332. For example, a signal line connected between the semiconductor chip 100 and the third side bump 323 may be the first signal line SL1. If the signal line, which is connected between the semiconductor chip 100 and the third side bump 323 disposed on the first side layer 320, is the first signal line SL1, the first signal S1 may be transferred to the semiconductor chip 100 through the first signal line SL1. Furthermore, a signal line, which is connected between the semiconductor chip 100 and the fourth side bump 324 disposed on the first side layer 320, may be the second signal line SL2. If the signal line, which is connected between the semiconductor chip 100 and the fourth side bump 324, is the second signal line SL2, the second signal S2 may be transferred to the semiconductor chip 100 through the second signal line SL2. In the same way, a power line, which is connected between the semiconductor chip 100 and the seventh side bump 332 disposed on the second side layer 330, may be a first power line PL1. If the power line, which is connected between the semiconductor chip 100 and the seventh side bump 332, is the first power line PL1, the supply voltage VDD may be transferred to the semiconductor chip 100 through the first power line PL1.

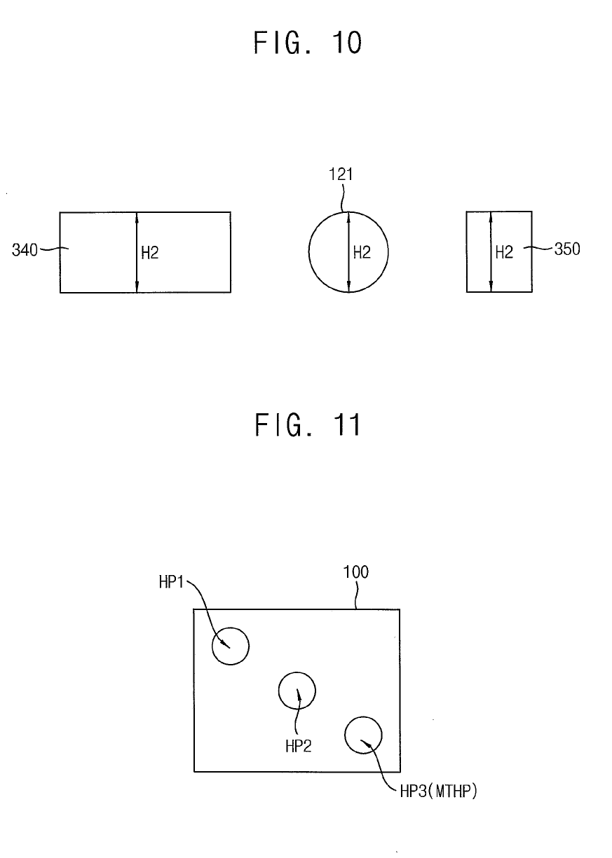

FIG. 9 is a diagram illustrating a semiconductor package according to an exemplary embodiment. FIG. 10 is a diagram explaining a height of a first additional side layer 340 and a second additional side layer 350 and the bump 121 included in the semiconductor package 10b of FIG. 9.

Referring to FIGS. 9 and 10, the semiconductor package 10b includes the semiconductor chip 100 and the extension die 300. The extension die 300 is attached to the semiconductor chip 100. The heating point HP corresponding to a point generating heat greater than or equal to the pre-determined reference temperature R_T in the semiconductor chip 100 is disposed in the center region CT_R corresponding to the center of the extension die 300. The extension die 300 includes an extension layer 310 and a first side layer 320 and a second side layer 330. The extension layer 310 may be attached to the first surface 110 of the semiconductor chip 100. For example, the first surface 110 of the semiconductor chip 100 may be connected to the extension layer 310, and the second surface 120 of the semiconductor chip 100 may be connected to the bumps 121 through 126. Each of the first and the second side layers 320 and 330 may be disposed on the extension layer 310 and may be attached to a side of the semiconductor chip 100.

In an exemplary embodiment, the extension die 300 may further include the first additional side layer 340 and the second additional side layer 350 disposed on the side layer 320 and 330, respectively. An additional side layer disposed on the first side layer 320 may be the first additional side layer 340. Heat, which is transferred from the heating point HP included in the semiconductor chip 100, may be transferred through the first additional side layer 340. Also, an additional side layer disposed on the second side layer 330 may be the second additional side layer 350. Heat, which is transferred from the heating point HP included in the semiconductor chip 100, may be transferred through the second additional side layer 350.

In an exemplary embodiment, the height of each of the first and second additional side layers 340 and 350 may be the same as the height of the bumps 121 through 126 attached to the second surface 120 of the semiconductor chip 100. For example, the height of the first bump 121 may be the second height H2. If the height of the first bump 121 is the second height H2, the height of the first additional side layer 340 may be the second height H2. Also, if the height of the first bump 121 is the second height H2, the height of the second additional side layer 350 may be the second height H2.

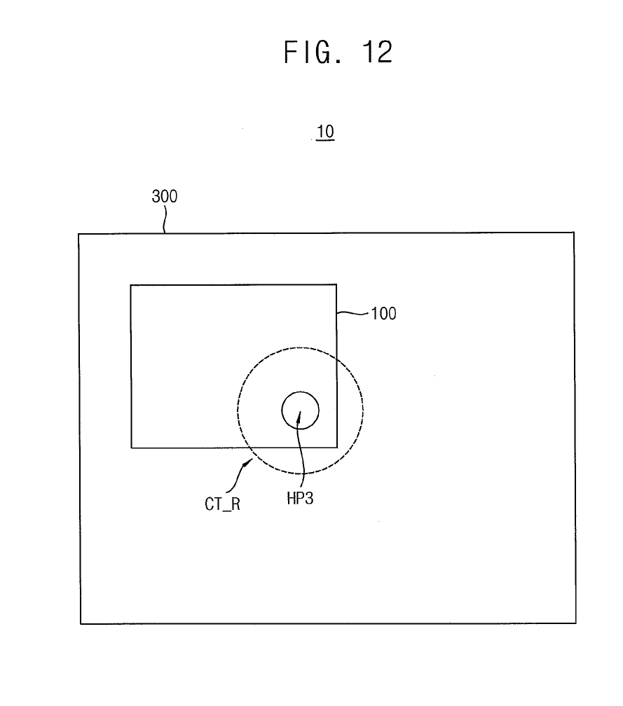

FIGS. 11 and 12 are diagrams explaining semiconductor package 10 according to an exemplary embodiment.

Referring to FIGS. 11 and 12, the semiconductor package 10 includes the semiconductor chip 100 and the extension die 300. The semiconductor chip 100 may include the heating point HP corresponding to a point generating heat greater than or equal to a pre-determined reference temperature R_T. The heating point HP may be determined in the test procedure of the semiconductor chip 100. The test procedure is executed prior to the packaging process combining the semiconductor chip 100 and the extension die 300.

The extension die 300 is attached to the semiconductor chip 100. The extension die 300 may include a material having high thermal conductivity. For example, the extension die 300 may be made with copper Cu and silicon Si. When the extension die 300 is made with the material having high thermal conductivity, the extension die 300 may effectively diffuse heat transferred from the heating point HP of the semiconductor chip 100. The extension die 300 may surround sides of the semiconductor chip 100. For example, the sides of the semiconductor chip 100 may include the first side 130, the second side 140, the third side 150, and the fourth side 160. For an exemplary embodiment, the extension die 300 may surround the first side 130, the second side 140, the third side 150, and the fourth side 160 of the semiconductor chip 100. For another exemplary embodiment, the extension die 300 may surround the first side 130 and the third side 150 of the semiconductor chip 100.

The heating point HP corresponding to a point generating heat greater than or equal to a pre-determined reference temperature R_T in the semiconductor chip 100 is disposed in a center region CT_R corresponding to the center of the extension die 300. For example, the pre-determined reference temperature R_T may be 120° C. In the test procedure of the semiconductor chip 100 which is executed prior to the packaging procedure combining the semiconductor chip 100 and the extension die 300, temperatures of a plurality of points included in the semiconductor chip 100 may be greater than or equal to 120° C. If temperatures of the plurality of the heating points included the semiconductor chip 100 are greater than or equal to 120° C., the plurality of heating points HP may exist. If the semiconductor chip 100 has the plurality of the heating points HP, a maximum temperature heating point MTHP corresponding to the highest temperature among the plurality of the heating points HP may be disposed in the center region CT_R of the extension die 300.

For example, the plurality of the heating points HP may include the first heating point HP1, the second heating point H2, and the third heating point H3. The temperature of the first heating point HP1 may be smaller than the temperature of the second heating point HP2, and the temperature of the second heating point HP2 may be smaller than the temperature of the third heating point HP3. If the temperature of the first heating point HP1 is smaller than the temperature of the second heating point HP2, and the temperature of the second heating point HP2 is smaller than the temperature of the third heating point HP3, the maximum temperature heating point MTHP may be the third heating point HP3. In this case, the third heating point HP3 may be disposed in the center region CT_R of the extension die 300.

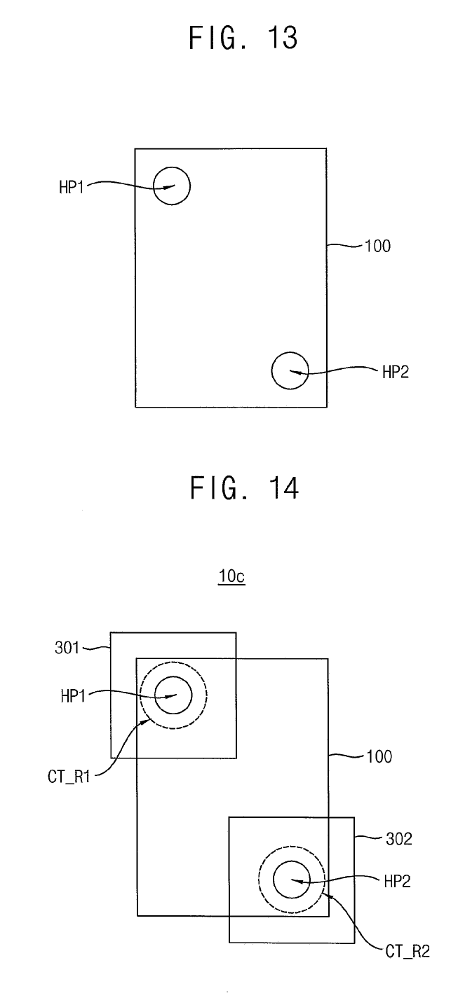

FIGS. 13 and 14 are diagrams explaining semiconductor package according to an exemplary embodiment.

Referring to FIGS. 13 and 14, the semiconductor package 10C includes the semiconductor chip 100 and the extension die 300. The semiconductor chip 100 may include the heating point HP corresponding to a point generating heat greater than or equal to a pre-determined reference temperature R_T. The extension die 300 is combined to the semiconductor chip 100. In an exemplary embodiment, if the semiconductor chip 100 includes the plurality of the heating points HP, the semiconductor package 10 may include a plurality of the extension dies 300.

For example, the plurality of the heating points HP may include the first heating point HP1 and the second heating point HP2. If the plurality of the heating points HP includes the first heating point HP1 and the second heating point HP2, the number of the extension die 300 may be two (2). The extension die 300 may include the first extension die 301 and the second extension die 302. The center region CT_R of the first extension die 301 may be the first center region CT_R1, and the center region CT_R of the second extension die 302 may be the second center region CT_R2. In the exemplary embodiment, the first heating point HP1 may be disposed on the first center region CT_R1 corresponding to the center region CT_R of the first extension die 301, and the second heating point HP2 may be disposed on the second center region CT_R2 corresponding to the center region CT_R of the second extension die 302. In an exemplary embodiment, each of the plurality of the heating points HP may be disposed in the center region CT_R of each of the plurality of the extension dies 300 corresponding to the plurality of the heating points HP.

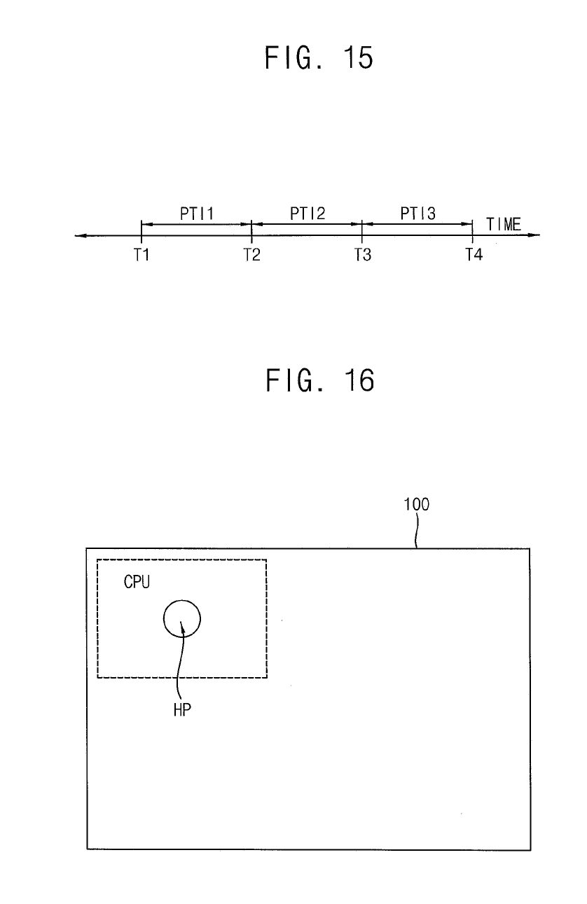

FIG. 15 is a diagram explaining an exemplary embodiment of a method to determine the heating point HP included in the semiconductor chip 100.

Referring to FIGS. 1 through 15, the heating point HP may be determined during a test procedure of the semiconductor chip 100. The test procedure is executed prior to a packaging process where the semiconductor chip 100 and the extension die 300 are combined. In an exemplary embodiment, if temperature of a certain point in the semiconductor chip 100 is greater than or equal to the reference temperature R_T during a pre-determined period, the certain point having the temperature higher than or equal to the reference temperature R_T may correspond to the heating point HP. For example, the pre-determined reference temperature R_T may be 120° C. The pre-determined period may be the first period PTI1. If temperature of the first point P1 of the semiconductor chip 100 is greater than or equal to 120° C. during the first period PTI1, the first point P1 may correspond to the heating point HP. On the other hand, if temperature of the first point P1 of the semiconductor chip 100 is less than 120° C. during the first period PTI1, the first point P1 may not correspond to the heating point HP.

For example, the pre-determined reference temperature R_T may be 120° C. The pre-determined period may be the second period PTI2. If average temperature of the first point P1 of the semiconductor chip 100 is greater than or equal to 120° C. during the second period PTI2, the first point P1 may correspond to the heating point HP. On the other hand, if average temperature of the first point P1 of the semiconductor chip 100 is less than 120° C. during the second period PTI2, the first point P1 may not correspond to the heating point HP.

For example, the pre-determined reference temperature R_T may be 120° C. The pre-determined period may be the third period PTI3. If the highest temperature of the first point P1 of the semiconductor chip 100 is greater than or equal to 120° C. during the third period PTI3, the first point P1 may correspond to the heating point HP. On the other hand, if the highest temperature of the first point P1 of the semiconductor chip 100 is less than 120° C. during the third period PTI3, the first point P1 may not correspond to the heating point HP. Therefore, the heating point HP may be determined based on various factors of the test procedure of the semiconductor chip 100 executed earlier than the packaging process combining the semiconductor chip 100 and the extension die 300.

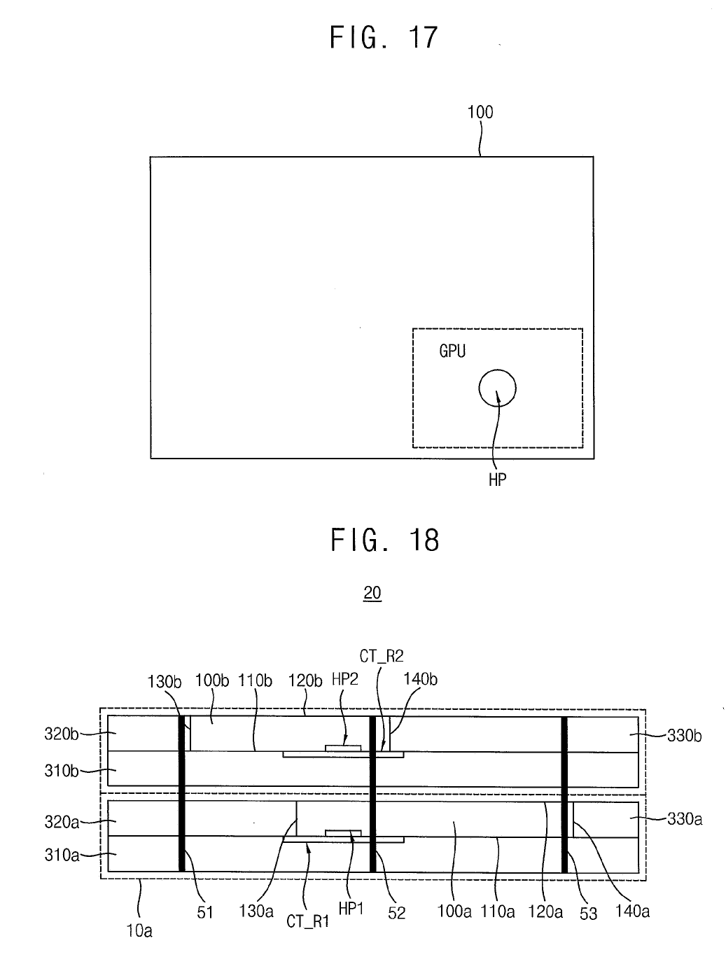

FIGS. 16 and 17 are diagrams explaining an exemplary embodiment of a method to determine the heating point HP included in the semiconductor chip 100.

Referring to FIGS. 1, 16, and 17, the semiconductor package 10 includes the semiconductor chip 100 and the extension die 300. The extension die 300 is combined to the semiconductor chip 100. The heating point HP corresponding to a point generating heat greater than or equal to the pre-determined reference temperature R_T in the semiconductor chip 100 is disposed in the center region CT_R corresponding to center of the extension die 300. In an exemplary embodiment, the heating point HP may be determined according to operation time of component included in the semiconductor chip 100.

For example, the semiconductor chip 100 may include a central processing unit CPU. Operation time of the central processing unit CPU included in the semiconductor chip 100 may be longer than operation time of other components included in the semiconductor chip 100. If operation time of the central processing unit CPU included in the semiconductor chip 100 is longer than operation time of other components included in the semiconductor chip 100, temperature of a point where the central processing unit CPU is disposed may increase. In this case, the heating point HP may be the point where the central processing unit CPU is disposed. In an exemplary embodiment, the heating point HP may be a point corresponding to the central processing unit CPU included in the semiconductor chip 100.

For example, the semiconductor chip 100 may include a graphic processing unit GPU. Operation time of the graphic processing unit GPU included in the semiconductor chip 100 may be longer than operation time of other components included in the semiconductor chip 100. If operation time of the graphic processing unit GPU included in the semiconductor chip 100 is longer than operation time of other components included in the semiconductor chip 100, temperature of a point where the graphic processing unit GPU is disposed may increase. In this exemplary embodiment, the heating point HP may be the point where the graphic processing unit GPU is disposed. In an exemplary embodiment, the heating point HP may be a point corresponding to the graphic processing unit GPU included in the semiconductor chip 100.

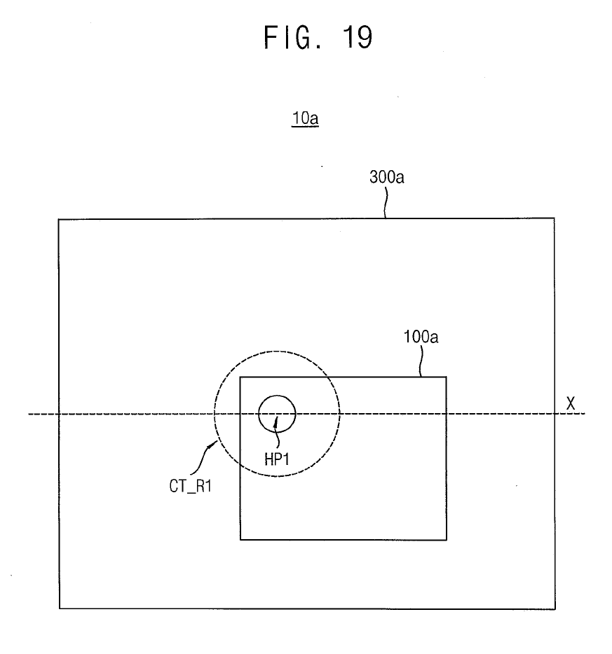

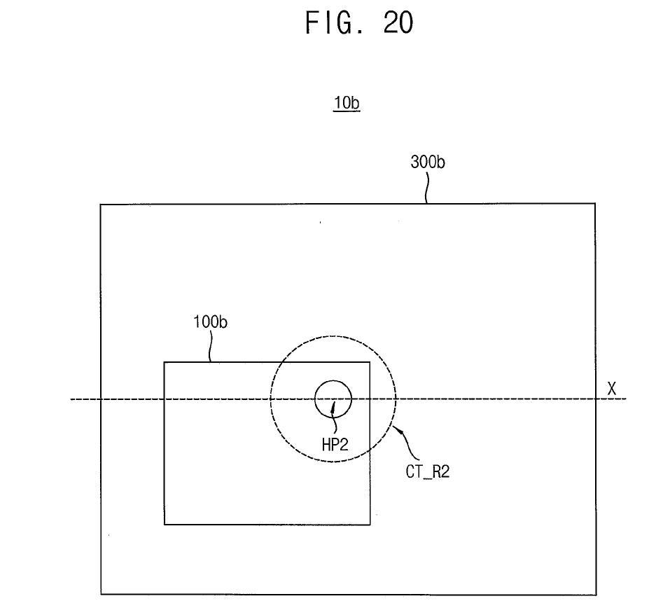

FIG. 18 is a diagram illustrating a three-dimensional semiconductor package 20 according to an exemplary embodiment. FIG. 19 is a diagram illustrating the first semiconductor package 10A included in the three-dimensional semiconductor package 20 of FIG. 18. FIG. 20 is a diagram illustrating the second semiconductor package 10B included in the three-dimensional semiconductor package 20 of FIG. 18.

Referring to FIGS. 18 through 20, a three-dimensional semiconductor package 20 includes a plurality of semiconductor packages 10A and 10B, and through silicon vias 51 through 53. Each of the plurality of the semiconductor packages 10A and 10B includes a semiconductor chip 100, and an extension die 300. The through silicon vias 51 through 53 connect the plurality of the semiconductor packages 10A and 10B. The semiconductor chip 100 may include the heating point HP corresponding to a point generating heat greater than or equal to a pre-determined reference temperature R_T. The heating point HP may be determined in a test procedure of the semiconductor chip 100. The test procedure is executed prior to packaging process combining the semiconductor chip 100 and the extension die 300.

The extension die 300 is combined to the semiconductor chip 100. The extension die 300 may include a material having high thermal conductivity. For example, the extension die 300 may be made with copper Cu and silicon Si. When the extension die 300 is made with the material having high thermal conductivity, the extension die 300 may effectively diffuse heat transferred from the heating point HP of the semiconductor chip 100. The extension die 300 may surround sides of the semiconductor chip 100. For example, the sides of the semiconductor chip 100 may include the first side 130, the second side 140, the third side 150, and the fourth side 160. For an exemplary embodiment, the extension die 300 may surround the first side 130, the second side 140, the third side 150, and the fourth side 160 of the semiconductor chip 100. For another exemplary embodiment, the extension die 300 may surround the first side 130 and the third side 150 of the semiconductor chip 100.

The heating point HP corresponding to a point generating heat greater than or equal to a pre-determined reference temperature R_T in the semiconductor chip 100 is disposed in a center region CT_R corresponding to the center of the extension die 300. For example, the pre-determined reference temperature R_T may be 120° C. In the test procedure of the semiconductor chip 100 which is executed earlier than the packaging procedure combining the semiconductor chip 100 and the extension die 300, temperature of the first point P1 included in the semiconductor chip 100 may be greater than or equal to 120° C. If temperature of the first point P1 included the semiconductor chip 100 is greater than or equal to 120° C., the first point P1 may be the heating point HP. If the first point P1 is the heating point HP, the first point P1 may be disposed in the center region CT_R corresponding to the center of the extension die 300. If the heating point HP is disposed in the center region CT_R corresponding to center of the extension die 300, heat transferred from the heating point HP may be diffused rapidly through the extension die 300. As described in the references to FIGS. 2A, 2B, and 2C, if the heating point HP is not disposed in the center region CT_R corresponding to the center of the extension die 300, heat transferred from the heating point HP may be diffused slowly through the extension die 300.

In an exemplary embodiment, a size of the extension die 300 may be larger than a size of the semiconductor chip 100. For example, the sides of the semiconductor chip 100 may include the first side 130, the second side 140, the third side 150, and a fourth side 160. The length of the first side 130 and the second side 140 of the semiconductor chip 100 may be a first length A. The length of the third side 150 and the fourth side 160 of the semiconductor chip 100 may be a second length B. A side of the extension die 300 corresponding to the first side 130 of the semiconductor chip 100 may be a first extension side 391. A side of the extension die 300 corresponding to the second side 140 of the semiconductor chip 100 may be a second extension side 392. A side of the extension die 300 corresponding to the third side 150 of the semiconductor chip 100 may be a third extension side 393. A side of the extension die 300 corresponding to the fourth side 160 of the semiconductor chip 100 may be a fourth extension side 394.

A length of the first extension side 391 and a length of the second extension side 392 of the extension die 300 may be a third length C, and a length of the third extension side 393 and a length of the fourth extension side 394 of the extension die 300 may be a fourth length D. The third length C may be larger than the first length A. The fourth length D may be larger than the second length B. In the exemplary embodiment, the size of the extension die 300 may be larger than the size of the semiconductor chip 100. If the size of the extension die 300 is larger than the size of the semiconductor chip 100, heat transferred from the heating point HP may be diffused rapidly through the extension die 300.

For example, the plurality of the semiconductor packages 10A and 10B may include the first semiconductor package 10A and the second semiconductor package 10B. The first semiconductor package 10A may include the first semiconductor chip 100A and the first extension die 300A. Also, the second semiconductor package 10B may include the second semiconductor chip 100B and the second extension die 300B. The through silicon vias may include the first through third through silicon vias 51 through 53. The first through third through silicon vias 51 through 53 may connect the first semiconductor package 10A and the second semiconductor package 10B. The first semiconductor chip 100A may include the first heating point HP1 corresponding to a point generating heat greater than or equal to a pre-determined reference temperature R_T. The first extension die 300A may be combined to the first semiconductor chip 100A. The first heating point HP1 corresponding to a point generating heat greater than or equal to the pre-determined reference temperature R_T in the first semiconductor chip 100A may be disposed in the first center region CT_R1 corresponding to the center of the first extension die 300A. Also, the second semiconductor chip 100B may include the second heating point HP2 corresponding to a point generating heat greater than or equal to a pre-determined reference temperature R_T. The second extension die 300B may be combined to the second semiconductor chip 100B. The second heating point HP2 corresponding to a point generating heat greater than or equal to the pre-determined reference temperature R_T in the second semiconductor chip 100B may be disposed in the second center region CT_R2 corresponding to the center of the second extension die 300B. The semiconductor package 10 according to exemplary embodiments may enhance heat transfer performance by disposing the heating point HP of the semiconductor chip 100 in the center region CT_R corresponding to center of the extension die 300.

Referring FIGS. 5 through 8 and 18 through 20, the extension die 300 may include the extension layer 310, the side layer 320 and 330, and the side bumps 321 through 325, 331, and 332. The extension layer 310 may be combined to the first surface 110 of the semiconductor chip 100. The side layer 320 and 330 may be disposed on the extension layer 310, and may be combined to a side of the semiconductor chip 100. The side bumps 321 through 325, 331, and 332 may be disposed on the side layers 320 and 330. For example, the first surface 110 of the semiconductor chip 100 may be connected to the extension layer 310, and the second surface 120 of the semiconductor chip 100 may be connected to the bumps 121 through 126. The extension layer 320 and 330 may be disposed on the extension layer 310 and may be combined to a side of the semiconductor chip 100.

For example, the side layer 320 and 330 may include a first side layer 320 and a second side layer 330. The first side layer 320 may be disposed on the extension layer 310 and may be combined to the first side 130 of the semiconductor chip 100. The second side layer 330 may be disposed on the extension layer 310 and may be combined to the second side 140 of the semiconductor chip 100. The extension layer 310 included in the extension die 300 may include a material having high thermal conductivity. For example, the extension layer 310 included in the extension die 300 may be made with copper Cu and silicon Si. When the extension layer 310 included in the extension die 300 is made with the material having high thermal conductivity, the extension layer 310 included in the extension die 300 may diffuse heat transferred from the heating point HP of the semiconductor chip 100 rapidly. Also, the first side layer 320 and the second side layer 330 included in the extension die 300 may be made with copper Cu and silicon Si. When the first side layer 320 and the second side layer 330 included in the extension die 300 is made with the material having high thermal conductivity, the extension layer 310 included in the extension die 300 may diffuse heat transferred from the heating point HP of the semiconductor chip 100 rapidly.

In an exemplary embodiment, the extension die 300 may further include the side bumps 321 through 325, 331, and 332 disposed on the side layer 320 and 330. For example, the side layer 320 and 330 may include the first side layer 320 and the second side layer 330. The side bumps disposed on the first side layer 320 may be the first through fifth side bumps 321 through 325. Also, the side bumps disposed on the second side layer 330 may be the sixth and seventh side bumps 331 and 332. Heat, which is transferred from the heating point HP included in the semiconductor chip 100, may be transferred through the first through fifth side bumps 321 through 325 and the sixth and seventh side bumps 331 and 332.

In an exemplary embodiment, the semiconductor package 10 may transfer signals through a signal line connected between the semiconductor chip 100 and the side bumps 321 through 325, 331, and 332. For example, a signal line connected between the semiconductor chip 100 and the third side bump 323 may be the first signal line SL1. If the signal line, which is connected between the semiconductor chip 100 and the third side bump 323 disposed on the first side layer 320, is the first signal line SL1, the first signal S1 may be transferred to the semiconductor chip 100 through the first signal line SL1. Furthermore, a signal line, which is connected between the semiconductor chip 100 and the fourth side bump 324 disposed on the first side layer 320, may be the second signal line SL2. If the signal line, which is connected between the semiconductor chip 100 and the fourth side bump 324, is the second signal line SL2, the second signal S2 may be transferred to the semiconductor chip 100 through the second signal line SL2. In the same way, a signal line, which is connected between the semiconductor chip 100 and the seventh side bump 332 disposed on the second side layer 330, may be the third signal line SL3. If the signal line, which is connected between the semiconductor chip 100 and the seventh side bump 332, is the third signal line SL3, the third signal S3 may be transferred to the semiconductor chip 100 through the third signal line SL3.

In an exemplary embodiment, the semiconductor package 10 may transfer a supply voltage VDD through a power line connected between the semiconductor chip 100 and the side bumps 321 through 325, 331, and 332. For example, a signal line connected between the semiconductor chip 100 and the third side bump 323 may be the first signal line SL1. If the signal line, which is connected between the semiconductor chip 100 and the third side bump 323 disposed on the first side layer 320, is the first signal line SL1, the first signal S1 may be transferred to the semiconductor chip 100 through the first signal line SL1. Furthermore, a signal line, which is connected between the semiconductor chip 100 and the fourth side bump 324 disposed on the first side layer 320, may be the second signal line SL2. If the signal line, which is connected between the semiconductor chip 100 and the fourth side bump 324, is the second signal line SL2, the second signal S2 may be transferred to the semiconductor chip 100 through the second signal line SL2. In the same way, a power line, which is connected between the semiconductor chip 100 and the seventh side bump 332 disposed on the second side layer 330, may be the first power line PL1. If the power line, which is connected between the semiconductor chip 100 and the seventh side bump 332, is the first power line PL1, the supply voltage VDD may be transferred to the semiconductor chip 100 through the first power line PL1.

Referring to FIGS. 9, 10, and 18 through 20, the extension die 300 may include the extension layer 210, the side layer 320 and 330, and the additional side layer 340 and 350. The extension layer 310 may be combined to the first surface 110 of the semiconductor chip 100. The side layer 320 and 330 may be disposed on the extension layer 310, and may be combined to a side of the semiconductor chip 100. The additional side layer 340 and 350 may be disposed on the side layer 320 and 330. For example, the side layer 320 and 330 may include the first side layer 320 and the second side layer 330. An additional side layer disposed on the first side layer 320 may be the first additional side layer 340. Heat, which is transferred from the heating point HP included in the semiconductor chip 100, may be transferred through the first additional side layer 340. Also, an additional side layer disposed on the second side layer 330 may be the second additional side layer 350. Heat, which is transferred from the heating point HP included in the semiconductor chip 100, may be transferred through the second additional side layer 350.

In an exemplary embodiment, the height of the additional side layer 340 and 350 may be the same as the height of the bumps 121 through 126 combined to the second surface 120 of the semiconductor chip 100. For example, the height of the first bump 121 may be the second height H2. If the height of the first bump 121 is the second height H2, the height of the first additional side layer 340 may be the second height H2. Also, if the height of the first bump 121 is the second height H2, the height of the second additional side layer 350 may be the second height H2.

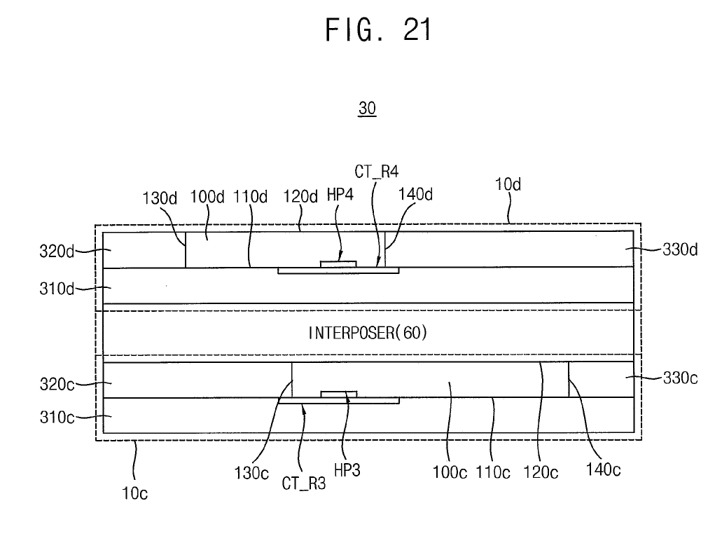

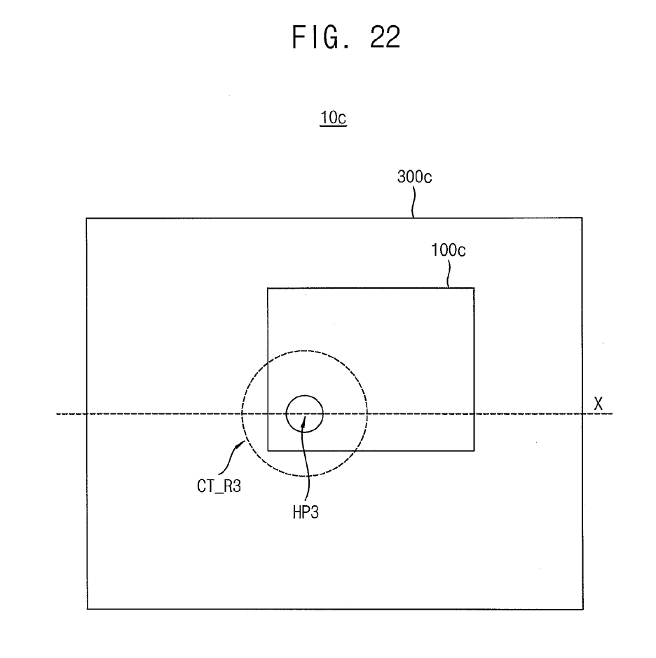

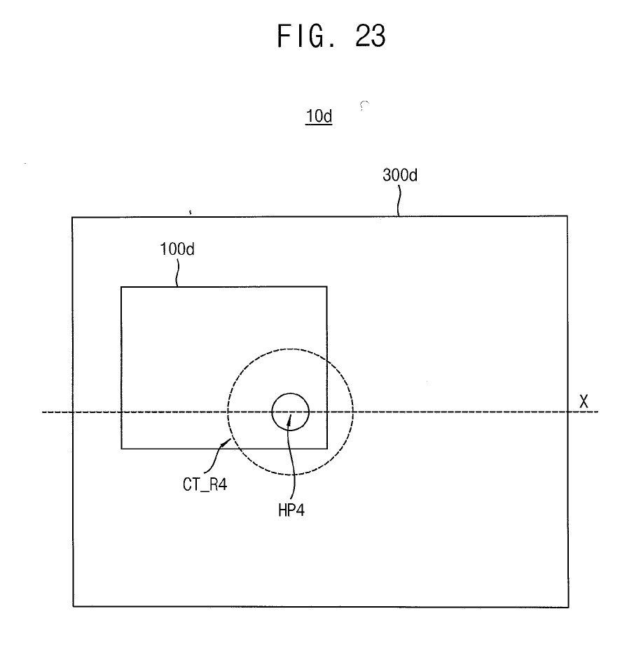

FIG. 21 is a diagram illustrating a three-dimensional semiconductor package according to exemplary embodiments. FIG. 22 is a diagram illustrating the third semiconductor package included in the three-dimensional semiconductor package of FIG. 21. FIG. 23 is a diagram illustrating the fourth semiconductor package included in the three-dimensional semiconductor package of FIG. 21.

Referring to FIGS. 21 through 23, a three-dimensional semiconductor package 30 includes a plurality of semiconductor packages 10C and 10D and an interposer 60. Each of the plurality of semiconductor packages 10C and 10D includes a semiconductor chip 100 and an extension die 300. The interposer 60 connects the plurality of the semiconductor packages 10C and 10D. The semiconductor chip 100 may include the heating point HP corresponding to a point generating heat greater than or equal to a pre-determined reference temperature R_T. The heating point HP may be determined in a test procedure of the semiconductor chip 100. The test procedure is executed prior to packaging process combining the semiconductor chip 100 and the extension die 300.

The extension die 300 is combined to the semiconductor chip 100. The extension die 300 may include a material having high thermal conductivity. For example, the extension die 300 may be made with copper Cu and silicon Si. When the extension die 300 is made with the material having high thermal conductivity, the extension die 300 may diffuse heat transferred from the heating point HP of the semiconductor chip 100. The extension die 300 may surround sides of the semiconductor chip 100. For example, the sides of the semiconductor chip 100 may include a first side 130, a second side 140, a third side 150, and a fourth side 160. For an exemplary embodiment, the extension die 300 may surround the first side 130, the second side 140, the third side 150, and the fourth side 160 of the semiconductor chip 100. For an exemplary embodiment, the extension die 300 may surround the first side 130 and the third side 150 of the semiconductor chip 100.

The heating point HP corresponding to a point generating heat greater than or equal to a pre-determined reference temperature R_T in the semiconductor chip 100 is disposed in a center region CT_R corresponding to center of the extension die 300. For example, the pre-determined reference temperature R_T may be 120° C. In the test procedure of the semiconductor chip 100 which is executed earlier than the packaging procedure combining the semiconductor chip 100 and the extension die 300, temperature of the first point P1 included in the semiconductor chip 100 may be greater than or equal to 120° C. If temperature of the first point P1 included the semiconductor chip 100 is greater than or equal to 120° C., the first point P1 may be the heating point HP. If the first point P1 is the heating point HP, the first point P1 may be disposed in the center region CT_R corresponding to center of the extension die 300. If the heating point HP is disposed in the center region CT_R corresponding to center of the extension die 300, heat transferred from the heating point HP may be diffused rapidly through the extension die 300. As described in the references to FIGS. 2A, 2B, and 2C, if the heating point HP is not disposed in the center region CT_R corresponding to center of the extension die 300, heat transferred from the heating point HP may be diffused slowly through the extension die 300.

For example, the plurality of the semiconductor package 10C and 10D may include the third semiconductor package 10C and the fourth semiconductor package 10D. The third semiconductor package 10C may include the third semiconductor chip 100C and the third extension die 300C. Also, the fourth semiconductor package 10D may include the fourth semiconductor chip 100D and the fourth extension die 300D. The third semiconductor chip 100C may include the third heating point HP3 corresponding to a point generating heat greater than or equal to a pre-determined reference temperature R_T. The third extension die 300C may be combined to the third semiconductor chip 100C. The third heating point HP3 corresponding to a point generating heat greater than or equal to the pre-determined reference temperature R_T in the third semiconductor chip 100C may be disposed in the third center region CT_R3 corresponding to center of the third extension die 300C. Also, the fourth semiconductor chip 100D may include the fourth heating point HP4 corresponding to a point generating heat greater than or equal to a pre-determined reference temperature R_T. The fourth extension die 300D may be combined to the fourth semiconductor chip 100D. The fourth heating point HP4 corresponding to a point generating heat greater than or equal to the pre-determined reference temperature R_T in the fourth semiconductor chip 100D may be disposed in the fourth center region CT_R4 corresponding to center of the fourth extension die 300D. The semiconductor package 10 according to exemplary embodiments may enhance heat transfer performance by disposing the heating point HP of the semiconductor chip 100 in the center region CT_R corresponding to the center of the extension die 300.

In an exemplary embodiment, the heating point HP may be determined in the test procedure of the semiconductor chip 100. If temperature of a certain point in the semiconductor chip 100 is greater than or equal to the reference temperature R_T during a pre-determined period, the certain point may correspond to the heating point HP. For example, the pre-determined reference temperature R_T may be 120° C. The pre-determined period may be the first period PTI1. If temperature of the first point P1 of the semiconductor chip 100 is greater than or equal to 120° C. during the first period PTI1, the first point P1 may correspond to the heating point HP. On the other hand, if temperature of the first point P1 of the semiconductor chip 100 is less than 120° C. during the first period PTI1, the first point P1 may not correspond to the heating point HP.

For example, the pre-determined reference temperature R_T may be 120° C. The pre-determined period may be the second period PTI2. If average temperature of the first point P1 of the semiconductor chip 100 is greater than or equal to 120° C. during the second period PTI2, the first point P1 may correspond to the heating point HP. On the other hand, if average temperature of the first point P1 of the semiconductor chip 100 is less than 120° C. during the second period PTI2, the first point P1 may not correspond to the heating point HP.

For example, the pre-determined reference temperature R_T may be 120° C. The pre-determined period may be the third period PTI3. If the highest temperature of the first point P1 of the semiconductor chip 100 is greater than or equal to 120° C. during the third period PTI3, the first point P1 may correspond to the heating point HP. On the other hand, if the highest temperature of the first point P1 of the semiconductor chip 100 is less than 120° C. during the third period PTI3, the first point P1 may not correspond to the heating point HP. Therefore, the heating point HP may be determined based on various factors of the test procedure of the semiconductor chip 100 executed prior to the packaging process combining the semiconductor chip 100 and the extension die 300. The semiconductor package 10 according to exemplary embodiments may enhance heat transfer performance by disposing the heating point HP of the semiconductor chip 100 in the center region CT_R corresponding to the center of the extension die 300.

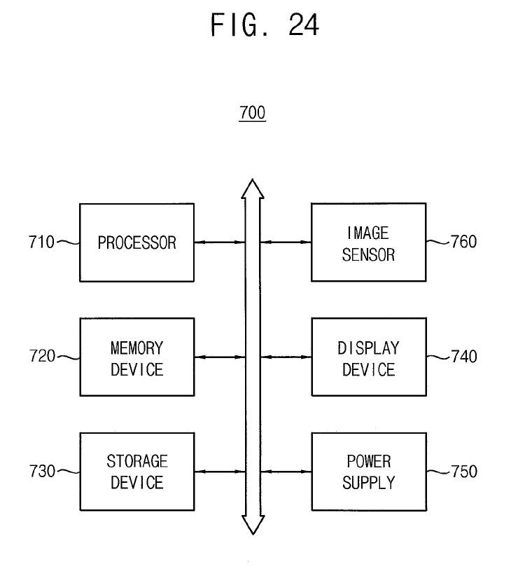

FIG. 24 is a block diagram illustrating an exemplary embodiment of a mobile system applying the semiconductor package according to an exemplary embodiment.

Referring to FIG. 24, a mobile device 700 may include a processor 710, a memory device 720, a storage device 730, a display device 740, a power supply 750 and an image sensor 760. The mobile device 700 may further include ports that communicate with a video card, a sound card, a memory card, a USB device, other electronic devices, etc.

The processor 710 may perform various calculations or tasks. According to exemplary embodiments, the processor 710 may be a microprocessor or a CPU. The processor 710 may communicate with the memory device 720, the storage device 730, and the display device 740 via an address bus, a control bus, and/or a data bus. In an exemplary embodiment, the processor 710 may be coupled to an extended bus, such as a peripheral component interconnection (PCI) bus. The memory device 720 may store data for operating the mobile device 700. For example, the memory device 720 may be implemented with a dynamic random access memory (DRAM) device, a mobile DRAM device, a static random access memory (SRAM) device, a phase-change random access memory (PRAM) device, a ferroelectric random access memory (FRAM) device, a resistive random access memory (RRAM) device, and/or a magnetic random access memory (MRAM) device. The memory device 720 includes the data loading circuit according to exemplary embodiments. The storage device 730 may include a solid state drive (SSD), a hard disk drive (HDD), a CD-ROM, etc. The mobile device 700 may further include an input device such as a touch screen, a keyboard, a keypad, a mouse, etc., and an output device such as a printer, a display device, etc. The power supply 750 supplies operation voltages for the mobile device 700.

The image sensor 760 may communicate with the processor 710 via the buses or other communication links. The image sensor 760 may be integrated with the processor 710 in one chip, or the image sensor 760 and the processor 710 may be implemented as separate chips.

At least a portion of the mobile device 700 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP). The mobile device 700 may be a digital camera, a mobile phone, a smart phone, a portable multimedia player (PMP), a personal digital assistant (PDA), a computer, etc.

In addition, in an exemplary embodiment of the present disclosure, a three dimensional (3D) memory array is provided in the memory device 720. The 3D memory array is monolithically formed in one or more physical levels of arrays of memory cells having an active area disposed above a silicon substrate and circuitry associated with the operation of those memory cells, whether such associated circuitry is above or within such substrate. The term “monolithic” means that layers of each level of the array are directly deposited on the layers of each underlying level of the array. The following patent documents, which are hereby incorporated by reference, describe suitable configurations for the 3D memory arrays, in which the three-dimensional memory array is configured as a plurality of levels, with word-lines and/or bit-lines shared between levels: U.S. Pat. Nos. 7,679,133; 8,553,466; 8,654,587; 8,559,235; and US Pat. Pub. No. 2011/0233648.

The semiconductor package 10 according to the exemplary embodiments may be included in the mobile system 700. The semiconductor package 10 according to exemplary embodiments may enhance heat transfer performance by disposing the heating point HP of the semiconductor chip 100 in the center region CT_R corresponding to center of the extension die 300.

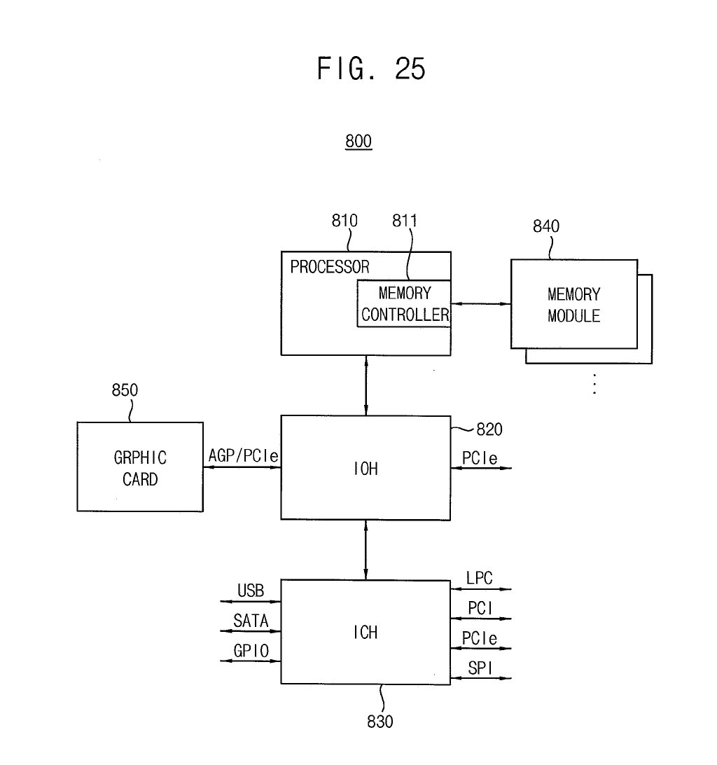

FIG. 25 is a block diagram illustrating an exemplary embodiment of a computing system applying the semiconductor package 10 according to exemplary embodiments.

Referring to FIG. 25, a computing system 800 includes a processor 810, an input/output hub (IOH) 820, an input/output controller hub (ICH) 830, at least one memory module 840 and a graphics card 850. In exemplary embodiments, the computing system 800 may be a personal computer (PC), a server computer, a workstation, a laptop computer, a mobile phone, a smart phone, a personal digital assistant (PDA), a portable multimedia player (PMP), a digital camera), a digital television, a set-top box, a music player, a portable game console, a navigation system, etc.

The processor 810 may perform various computing functions, such as executing specific software for performing specific calculations or tasks. For example, the processor 810 may be a microprocessor, a central process unit (CPU), a digital signal processor, or the like. In some embodiments, the processor 810 may include a single core or multiple cores. For example, the processor 810 may be a multi-core processor, such as a dual-core processor, a quad-core processor, a hexa-core processor, etc. In some embodiments, the computing system 800 may include a plurality of processors. The processor 810 may include an internal or external cache memory.

The processor 810 may include a memory controller 811 for controlling operations of the memory module 840. The memory controller 811 included in the processor 810 may be referred to as an integrated memory controller (IMC). A memory interface between the memory controller 811 and the memory module 840 may be implemented with a single channel including a plurality of signal lines, or may bay be implemented with multiple channels, to each of which at least one memory module 840 may be coupled. In some embodiments, the memory controller 811 may be located inside the input/output hub 820, which may be referred to as memory controller hub (MCH).

The input/output hub 820 may manage data transfer between processor 810 and devices, such as the graphics card 850. The input/output hub 820 may be coupled to the processor 810 via various interfaces. For example, the interface between the processor 810 and the input/output hub 820 may be a front side bus (FSB), a system bus, a HyperTransport, a lightning data transport (LDT), a QuickPath interconnect (QPI), a common system interface (CSI), etc. In some embodiments, the computing system 800 may include a plurality of input/output hubs. The input/output hub 820 may provide various interfaces with the devices. For example, the input/output hub 820 may provide an accelerated graphics port (AGP) interface, a peripheral component interface-express (PCIe), a communications streaming architecture (CSA) interface, etc.

The graphics card 850 may be coupled to the input/output hub 820 via AGP or PCIe. The graphics card 850 may control a display device (not shown) for displaying an image. The graphics card 850 may include an internal processor for processing image data and an internal memory device. In some embodiments, the input/output hub 820 may include an internal graphics device along with or instead of the graphics card 850 outside the graphics card 850. The graphics device included in the input/output hub 820 may be referred to as integrated graphics. Further, the input/output hub 820 including the internal memory controller and the internal graphics device may be referred to as a graphics and memory controller hub (GMCH).

The input/output controller hub 830 may perform data buffering and interface arbitration to efficiently operate various system interfaces. The input/output controller hub 830 may be coupled to the input/output hub 820 via an internal bus, such as a direct media interface (DMI), a hub interface, an enterprise Southbridge interface (ESI), PCIe, etc. The input/output controller hub 830 may provide various interfaces with peripheral devices. For example, the input/output controller hub 830 may provide a universal serial bus (USB) port, a serial advanced technology attachment (SATA) port, a general purpose input/output (GPIO), a low pin count (LPC) bus, a serial peripheral interface (SPI), PCI, PCIe, etc.

In exemplary embodiments, the processor 810, the input/output hub 820 and the input/output controller hub 830 may be implemented as separate chipsets or separate integrated circuits. In other embodiments, at least two of the processor 810, the input/output hub 820 and the input/output controller hub 830 may be implemented as a single chipset.

The semiconductor package 10 according to exemplary embodiments may be included in the computing system 800. The semiconductor package 10 according to exemplary embodiments may enhance heat transfer performance by disposing the heating point HP of the semiconductor chip 100 in the center region CT_R corresponding to the center of the extension die 300.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

1. A semiconductor package comprising:
a semiconductor chip; and
an extension die provided on the semiconductor chip,
wherein the semiconductor chip includes a heating point configured to generate a temperature greater than or equal to a pre-determined reference temperature in the semiconductor chip, the heating point provided in a center region of the extension die.

2. The semiconductor package of claim 1, wherein a size of the extension die is larger than a size of the semiconductor chip.

3. The semiconductor package of claim 1, wherein the extension die comprises:
an extension layer attached to a first surface of the semiconductor chip; and
a side layer which is provided on the extension layer and which is attached to a side of the semiconductor chip.

4. The semiconductor package of claim 3, wherein a height of the side layer is equal to a height of the semiconductor chip.

5. The semiconductor package of claim 3, wherein the extension die further comprises side bumps provided on the side layer.

6. The semiconductor package of claim 5, wherein sizes of the side bumps are equal to sizes of bumps attached to a second surface of the semiconductor chip.

7. The semiconductor package of claim 5, wherein the semiconductor package is configured to transfer signals through a signal line connected between the semiconductor chip and the side bumps.

8. The semiconductor package of claim 5, wherein the semiconductor package is configured to transfer a supply voltage through a power line connected between the semiconductor chip and the side bumps.

9. The semiconductor package of claim 3, wherein the extension die further comprises an additional side layer provided on the side layer.

10. The semiconductor package of claim 9, wherein a height of the additional side layer is equal to a height of the bumps attached to a second surface of the semiconductor chip.

11. The semiconductor package of claim 1, wherein the heating point is pre-determined in a test procedure of the semiconductor chip.

12. The semiconductor package of claim 11, wherein the heating point corresponds to a point having a temperature greater than or equal to the pre-determined temperature, on the semiconductor chip.

13. The semiconductor package of claim 12, wherein in response to the semiconductor chip including a plurality of the heating points, a maximum temperature heating point corresponding to a heating point having the highest temperature among the plurality of the heating points is provided in the center region of the extension die.

14.-15. (canceled)

16. The semiconductor package of claim 12, wherein in response to a temperature of a certain point in the semiconductor chip being greater than or equal to the reference temperature during a pre-determined period, the certain point corresponds to the heating point.

17. The semiconductor package of claim 11, wherein the heating point is determined according to an operation time of a component included in the semiconductor chip.

18. The semiconductor package of claim 1, wherein the heating point corresponds to a location of a central processing unit (CPU) included in the semiconductor chip.

19. The semiconductor package of claim 1, wherein the heating point corresponds to a location of a graphic processing unit (GPU) included in the semiconductor chip.

20. A three-dimensional semiconductor package comprising:
a plurality of semiconductor packages; and
a via connecting the plurality of the semiconductor packages,
wherein each of the plurality of the semiconductor packages includes:
a semiconductor chip; and
an extension die provided on the semiconductor chip,
wherein the semiconductor chip includes a heating point configured to generate a temperature greater than or equal to a pre-determined reference temperature in the semiconductor chip, the heating point provided in a center region of the extension die.

21. The three-dimensional semiconductor package of claim 20, wherein the via comprises through silicon vias.

22-26. (canceled)

27. A semiconductor package comprising:
a semiconductor chip comprising a heating point configured to generate a temperature greater than or equal to a pre-determined reference temperature in the semiconductor chip; and
an extension die attached to the semiconductor chip and configured to diffuse heat from the heating point of the semiconductor chip,
wherein the extension die is attached to the semiconductor chip such that the heating point of the semiconductor chip is disposed in a center region of the extension die.

28.-29. (canceled)
